(19) United States
(12) Patent Application Publication
(10) Pub. No.: US 2021/0294407 A1
(43) Pub. Date: Sep. 23, 2021

(54) SETTING A POWER MODE BASED ON A WORKLOAD LEVEL IN A MEMORY SUB-SYSTEM

(71) Applicant: Micron Technology, Inc., Boise, ID (US)

(72) Inventors: Liang Yu, Boise, ID (US); Jonathan Parry, Boise, ID (US)

(21) Appl. No.: 16/821,579

(22) Filed: Mar. 17, 2020

(51) Int. Cl. G06F 1/3234; G06F 1/3296; G11C 5/14

(52) U.S. Cl. CPC G06F 1/3243; G11C 5/14; G06F 1/3296

(57) ABSTRACT

A workload level in an incoming request queue is determined based on one or more operations requested by a host system for execution by a memory sub-system. Based on the workload level in the incoming request queue, a set of memory dies of the memory sub-system to be activated for execution of the one or more operations is identified. Based on a power budget level, a power mode configuration for a memory die of the set of memory dies is determined. One or more parameters of the memory die are configured to establish the power mode configuration.

### TECHNICAL FIELD

Embodiments of the disclosure relate generally to memory sub-systems, and more specifically, relate to setting a power mode based on a workload level in a memory sub-system.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1 illustrates an example computing system that includes a memory sub-system in accordance with some embodiments of the present disclosure.

FIG. 2 is a flow diagram of an example method to establish a power mode configuration for a memory die in accordance with some embodiments.

FIG. 3 illustrates an example system including a power mode management component configured to establish a power mode configuration for one or more memory dies in accordance with some embodiments in accordance with some embodiments.

FIG. 4 is a table including example power mode configurations as determined by a power mode management component in accordance with some embodiments.

FIG. 5 is a table including example power mode configurations as determined by a power mode management component in accordance with some embodiments.

FIG. 6 is a block diagram of an example computer system in which implementations of the present disclosure can operate.

### DETAILED DESCRIPTION

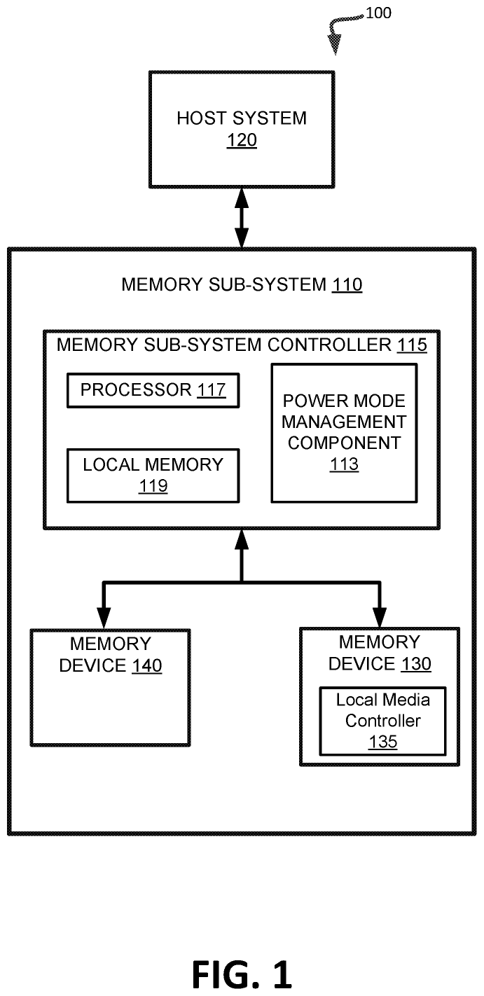

Aspects of the present disclosure are directed to setting a power mode based on a workload level in a memory sub-system. A memory sub-system can be a storage device, a memory module, or a hybrid of a storage device and memory module. Examples of storage devices and memory modules are described below in conjunction with FIG. 1. In general, a host system can utilize a memory sub-system that includes one or more components, such as memory devices that store data. The host system can provide data to be stored at the memory sub-system and can request data to be retrieved from the memory sub-system.

A memory sub-system can perform multiple parallel operations (e.g., random reads, sequential reads, random writes, sequential writes, etc.) involving multiple memory devices having multiple memory die. The parallel performance of operations involving multiple memory devices results in the consumption of higher current and higher power demands on a power supply which negatively impacts the stability and reliability of the data. To address power issues resulting from overlapping operations, conventional memory devices employ a power budget to set a level or limit within which the multiple multi-die memory devices can operate during the execution of concurrent operations. However, this approach results in the establishing of one pre-defined power performance level based on a particular memory device design. Accordingly, a controller in a conventional system is constrained by the pre-defined peak performance level and forced to limit the number of memory dies that can be active at a given time to perform parallel program and read operations. Furthermore, a conventional power management approach can be implemented by pausing operation execution algorithms of one or more memory devices in response to identifying an overlap of multiple power instances corresponding to concurrently executing memory dies. However, algorithm pausing, which can result in a pause of 5 to 10 microseconds, is not effective for certain short-duration or fast operations (e.g., snap read operations, single level cell (SLC) program operations) which have a short execution duration (e.g., 50 microseconds), which results in a significant performance penalty (e.g., approximately a 30% performance penalty).

Aspects of the present disclosure address the above and other deficiencies by a memory sub-system that can selectively set a power mode configuration for one or more memory die of one or more memory packages. A controller of the memory sub-system can transition one or more individual dies or memory packages (e.g., a set of multiple dies) between multiple power mode configurations by setting one or more parameters corresponding to a power level of the respective memory die. The multiple power mode configurations can include a default or medium power mode configuration (e.g., where one or more power mode parameters of a memory die are configured to establish a threshold power level), a low power mode configuration (e.g., where one or more power mode parameters of a memory die are configured to establish a power level below the threshold power level) and a high power mode configuration (e.g., where one or more power mode parameters of a memory die are configured to establish a power level above the threshold power level).

The memory sub-system controller can monitor a power budget request from the host system. In parallel, the controller can track the task requests (e.g., requests for operations) issued by the host system to determine a workload level in an incoming request queue. The controller can determine a number of memory dies to be accessed in parallel (e.g., a number of memory dies to be activated) based on the task workload level and types of operations (e.g., random reads, sequential reads, random writes, sequential writes, etc.) to be issued to the memory dies. The controller can calculate a power level corresponding to multiple different memory die configuration sets. Each memory die configuration set includes a number of memory dies to be activated in view of the identified workload level and a corresponding power mode (i.e., a medium power mode or a low power mode) for each of the activated memory dies.

Having determined the power levels for each of the multiple different memory die configuration sets, the controller selects and implements a desired memory die configuration to perform the identified workload within the limits of the requested power budget. In an embodiment, the controller can select a desired power mode from multiple power modes including a low power mode configuration exhibiting a power level below a threshold power level, a medium power mode configuration exhibiting a power level equal to the threshold power level, and a high power mode configuration exhibiting a power above the threshold power level. The desired power mode configuration can be established by sending a corresponding command at the die level (e.g., for each die individually, where the dies can be in different packages) or at the package level (e.g., for all die in a particular package). Each of the power mode configurations (e.g., the low, medium, and high power mode configurations) can be defined by a corresponding set of values or value ranges for one or more parameters associated with the memory die that impact the power level associated with the memory die (e.g., internal trim values, latch values, register values, flag values, a charge pump voltage level, a charge pump clock frequency, an internal bias current, a charge pump output resistance, an operation algorithm (e.g., a multiple plane parallel operation algorithm, a serialized single plane operation algorithm, etc.)

Advantageously, the system according to embodiments of the present disclosure selectively identifies and sets a desired power mode configuration for each memory die to enable an increase in throughput capability and optimization of the execution of operations in view of an applicable power budget. Furthermore, the system according to embodiments of the present disclosure effectively manages power budgets for short duration or fast operations (e.g., snap read operations, SLC program operations, etc.) with a lower performance penalty (e.g., 1 microsecond penalty), as compared to conventional operation pausing approaches.

FIG. 1 illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory module (NVDIMM).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to different types of memory sub-system 110. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), Small Computer System Interface (SCSI), a double data rate (DDR) memory bus, a dual in-line memory module (DIMM) interface (e.g., DIMM socket interface that supports Double Data Rate (DDR)), Open NAND Flash Interface (ONFI), Double Data Rate (DDR), Low Power Double Data Rate (LPDDR), or any other interface. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the PCIe interface. The physical host interface can provide an interface for passing control, address, data, and other signals between the memory sub-system 110 and the host system 120. FIG. 1 illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a negative-and (NAND) type flash memory and write-in-place memory, such as a three-dimensional cross-point (“3D cross-point”) memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices 130 can include one or more arrays of memory cells such as SLCs, MLCs, TLCs, QLCs, or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, and electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can be a processing device, which includes one or more processors (e.g., processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1 has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical block address (e.g., logical block address (LBA), namespace) and a physical block address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, a memory device 130 is a managed memory device, which is a raw memory device combined with a local controller (e.g., local controller 135) for media management within the same memory device package. An example of a managed memory device is a managed NAND (MNAND) device.

The memory sub-system 110 includes a power mode management component 113 that can monitor operation requests from the host system 120 to determine a workload level in an incoming request queue. Based on the workload level in the incoming request queue, the power mode management component 113 can identify a set of memory dies that are to be accessed or activated concurrently to perform the workload. The workload level in the incoming request queue can include a number and type of operations to be executed (e.g., read operations, write operations, random read operations, sequential read operations, etc.). The power mode management component 113 can further determine a power budget level (e.g., a total or maximum level of power that can be supplied to the one or more active memory dies).

In an embodiment, the power mode management component 113 selects, based on the power budget level, a number of memory dies in the set of memory dies to be activated, and characteristics related to power consumption associated with one or more operations to be performed, a power mode configuration for each of the activated memory die from a set of power mode configurations. In an embodiment, the set of power mode configurations can include a low power mode configuration, a medium power mode configuration, and a high power mode configuration. Each of the power mode configurations (e.g., the low, medium, and high power mode configurations) are associated with a set of values or value ranges for one or more parameters of the memory die (e.g., internal trim values, latch values, register values, flag values, a charge pump voltage level, a charge pump clock frequency, an internal bias current, a charge pump output resistance, an operation algorithm (e.g., a multiple plane parallel operation algorithm, a serialized single plane operation algorithm, etc.). The power mode management component 113 can place a memory die in the selected power mode configuration by configuring the one or more parameters to set the values corresponding to the selected power mode configuration.

A low power mode configuration can be established by setting one or more parameters of a memory die to a first set of values such that a resulting power level is below a threshold power level. A medium power mode configuration can be can be established by setting one or more parameters of a memory die to a second set of values such that a resulting power level is equal to the threshold power level. A high power mode configuration can be can be established by setting one or more parameters of a memory die to a third set of values such that the resulting power level is above the threshold power level.

In an embodiment, the first set of parameter values, second set of parameter values and third set of parameter values used to define or establish the respective low power mode, medium power mode, or high power mode can be preset during manufacturing of the memory device or established by the power mode management component 113.

Upon selection of the power mode configuration (e.g., low, regular, or high) for a memory die, the power mode management component 113 configures one or more parameters of the memory die to set the desired power mode configuration. In an embodiment, the power mode management component 113 can configure or set the one or more parameters before execution of the one or more operations or during execution of the one or more operations. The parameters of the memory die that are configured to set the selected power mode configuration can include, for example, internal trim values, latches, registers, flags, a charge pump voltage level, a charge pump clock frequency, an internal bias current, a charge pump output resistance, an operation algorithm (e.g., a multiple plane parallel operation algorithm, a serialized single plane operation algorithm, etc.), etc.

In an embodiment, the power mode management component 113 can set the desired power mode configuration for each memory die individually (e.g., including memory die located in different memory packages) by sending a command or command sequence (e.g., a set feature command sequence) via a suitable interface (e.g., a flash interface such as an Open NAND Flash Interface (ONFI) to set the one or more parameters of the memory die.

In an embodiment, the selected power mode configurations are established for the set of active memory die such that the total power associated with the execution of the workload is within or below the power budget. Advantageously, the power mode management component 113 monitors the task or workload requests from the host system 120 to determine the workload level in the incoming request queue.

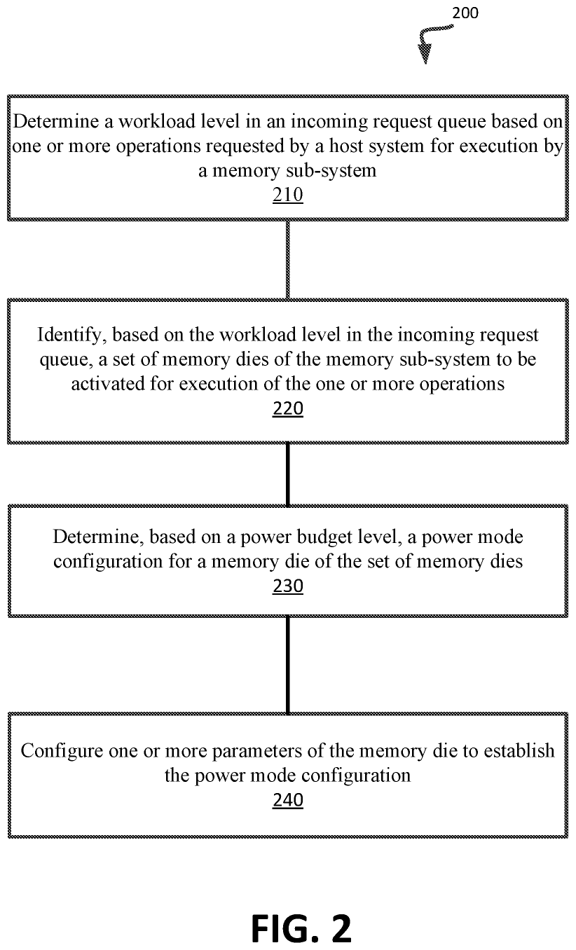

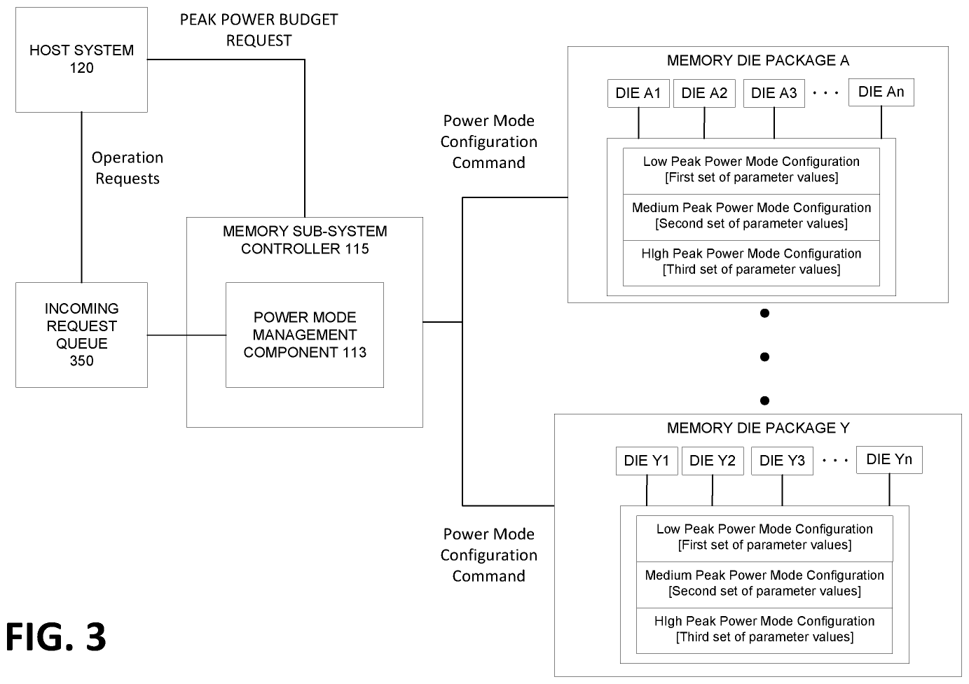

FIG. 2 is a flow diagram of an example method 200 to identify and establish a desired power mode configuration for one or more memory dies to be activated concurrently for the execution of one or more operations requested by a host system. The method 200 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 200 is performed by the power mode management component 113 of FIG. 1. In addition, FIG. 3 illustrates an example memory sub-system 115 including a power mode management component 113 configured to perform the operations of method 200. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

As shown in FIG. 2, at operation 210, the processing logic determines a workload level in the incoming request queue based on one or more operations requested by a host system for execution by a memory sub-system. In an embodiment, the workload level represents a number of tasks or operations, the amount of work (e.g., size of data payload, amount of data to be transferred, etc.), and the type of operations (e.g., read, write, random read, etc.) requested by a host system in association with one or more memory devices. In an embodiment, the processing logic monitors the one or more requests generated by the host system to determine the workload level in the incoming request queue.

In an embodiment, the workload level can represent a bandwidth level required by the host system to perform one or more operations. The bandwidth level can be determined based on the one or more requested operations. In an embodiment, the bandwidth level is based on a size of the data size to be written to or read from the one or more memory devices, in view of the operation requests in the incoming request queue. For example, the processing logic can determine the host system requires a sequential read bandwidth level of 2000 MB/s. In an embodiment, the power budget level and the bandwidth level can be determined in parallel by monitoring requests from the host system. In another example, the processing logic can determine the host system requires a sequential write bandwidth level of 900 MB/s.

As shown in FIG. 3, the power mode management component 113 can monitor an incoming request queue 350 identifying the one or more operation requests issued by the host system 120. In an embodiment, the task queue 350 can include a data structure stored in a storage location e.g., a cache memory accessible by the memory sub-system controller 115) that stores information relating to the one or more operation requests (e.g., an operation type, a corresponding bandwidth level, etc.) from the host system 120. In FIG. 3, the power mode management component 113 can monitor the host system 120 to identify a power request which identifies the power budget.

At operation 220, the processing logic identifies, based on the workload level in queue, a set of memory dies of the memory sub-system to be activated for execution of the one or more operations. In an embodiment, the processing device calculates the number of memory die to be activated (e.g., accessed in parallel) based on the workload level in the incoming request queue (e.g., the number of operations to be executed and the one or more types of those operations). In an embodiment, each type of operation (e.g., a random read operation, a sequential red operation, a random write operation, a sequential write operation, etc.) can be associated with a corresponding workload or bandwidth level as characterized by a corresponding power or current consumption associated with the execution of the particular operation type. In an embodiment, the workload level in the incoming request queue represents the number of operations to be executed and corresponding operation types are considered in calculating a number of memory die that are to be activated concurrently or in parallel in order to satisfy the workload level (e.g., complete the one or more operations). For example, the number of memory die employed during a sequential read operation can be determined based on a size of the read operation divided by an access unit size of each memory die. In an embodiment, the number of memory die activated to execute one or more random read operations can be determined based on a number of outstanding read requests in the queue divided by a total number of memory die. In an embodiment, a number of memory die to be activated on a sequential write can be determined based on a system bandwidth detected on a storage interface (e.g., a Universal Flash Storage) divided by a bandwidth level per each memory die. In the example shown in FIG. 3, the power mode management component 113 can identify a set of memory dies including memory dies A1, A2, A3 . . . An of memory die package A and memory dies Y1, Y2, Y3 . . . Yn of memory die package Y to perform the operations corresponding to the workload level in the incoming request queue.

At operation 230, the processing logic determines, based on a power budget level, a power mode configuration for a memory die of the set of memory dies. In an embodiment, the processing logic determines a power budget level by monitoring the host system to identify a power budget request. In an embodiment, the power budget request identifies a level or amount of total power that is budgeted or allocated for the performance of the workload level in the incoming request queue. For example, the power budget level can establish a value of 800 mA, such that the execution of the requested operation has a total or current level that can be consumed by the concurrently active memory die of 800 mA.

Having determined the number of memory die to activate (e.g., the number of memory dies to be accessed in parallel in order to execute the workload level in the incoming request queue), the processing logic can determine which power mode configuration to place each of active memory die in view of the power budget level and a corresponding level of current consumed by each memory die when in a respective power mode configuration. Each of the power mode configurations (e.g., low, medium, high) can be associated with a corresponding level of current consumed by each memory die when operating in the given power mode configuration. For example, a low power mode configuration can be associated with a current level of 100 mA per memory die, a medium power mode configuration can be associated with a current level of 200 mA per memory die, and a high power mode configuration can be associated with a current level of 400 mA per memory die. In an embodiment, the processing logic determines the number of the memory dies that are to be placed into one or more of the power mode configurations in view of the corresponding current level for each power mode configurations such that the total current level of the set of memory dies is within the power budget level. For example, if the processing logic has a default total system power limit or budget of 800 mA, the processing logic and can calculate that two memory dies are to be placed in the high power mode configuration, four memory dies are to be placed in the medium power mode configuration, and eight memory dies are to be placed in the low power mode configuration. In an embodiment, the total system power limit can be configured by an end user or configured on-the-fly based on one or more parameters associated with the memory sub-system (e.g., battery level, temperature, etc.).

As shown in FIG. 3, the power mode management component 113 can identify one of the applicable power mode configurations (e.g., the low power mode configuration, the medium power mode configuration, and the high power mode configuration for each of the memory die at the memory die level or the memory die package level. As shown, each of the power mode configurations are associated with a corresponding set of parameter values.

At operation 240, the processing logic configures one or more parameters of the memory die to establish the power mode configuration. In an embodiment, the processing logic sets the one or more parameters of the memory die to the set of values corresponding to the selected power mode configuration. In an embodiment, the processing logic can configure the one or more parameters to a set of values corresponding to the desired power mode configuration. As in an example shown in FIG. 3, the power mode management component 113 can issue a power mode configuration command (e.g., a set feature command) to configure or tune the one or more parameters of a particular memory die (e.g., die A1) to a first set of parameters values to place the memory die in the low power mode configuration. In an embodiment, as shown in FIG. 3, the power mode management component 113 can issue a power mode configuration command to configure or tune the one or more parameters of a particular memory die (e.g., die A1) to a second set of parameters values to place the memory die in the regular power mode configuration. In an embodiment, as shown in FIG. 3, the power mode management component 113 can issue a power mode configuration command to configure or tune the one or more parameters of a particular memory die (e.g., die A1) to a third set of parameters values to place the memory die in the high power mode configuration.

In an embodiment, the processing logic can configure a memory die to place the memory die in low power mode configuration (i.e., transition from a regular power mode configuration) by issuing a command sequence to set the values of one or more of the internal trims, latches, registers, flags, etc. to the first set of values to mark the requirement to reduce power during operations. In an embodiment, the processing logic can place a memory die in the low power mode configuration by configuring one or more of the following parameters to correspond to the first set of parameter values: a charge pump to a lower output voltage, slow down a charge pump clock frequency, limit an internal bias current, increase a charge pump output resistance, change an operation algorithm (e.g., switch from multiple plane parallel operations to serialized single plane operations), etc.

In an embodiment, the memory dies can be placed in a medium power mode by default (e.g., the default parameter values correspond to the second set of parameter values). In an embodiment, the processing logic can place the memory die in a low power mode configuration (i.e., transition from a regular power mode configuration) by issuing a command sequence to configure the values of one or more of the internal trims, latches, registers, flags, etc. to the first set of values to reduce the power level during operations (e.g., as compared to a threshold power level associated with the medium or default power mode configuration). In an embodiment, the processing logic can place a memory die in the low power mode configuration by configuring one or more of the following parameters to correspond to the first set of parameter values to set a charge pump to a lower output voltage, slow down a charge pump clock frequency, limit an internal bias current, increase a charge pump output resistance, change an operation algorithm (e.g., switch from multiple plane parallel operations to serialized single plane operations), etc.

In an embodiment, the processing logic can place the memory die in a high power mode configuration (i.e., transition from a regular power mode configuration) by issuing a command sequence to configure the values of one or more of the internal trims, latches, registers, flags, etc. to the third set of values to increase the power level during operations (e.g., as compared to the threshold power level associate with the medium or default power mode configuration). In an embodiment, the processing logic can place a memory die in the high power mode configuration by configuring one or more of the following parameters to correspond to the third set of parameter values to set a charge pump to a higher output voltage, speed up a charge pump clock frequency, increase internal bias current, decrease a charge pump output resistance, change an operation algorithm (e.g., switch from serialized single plane operations to multiple plane parallel operations), etc.

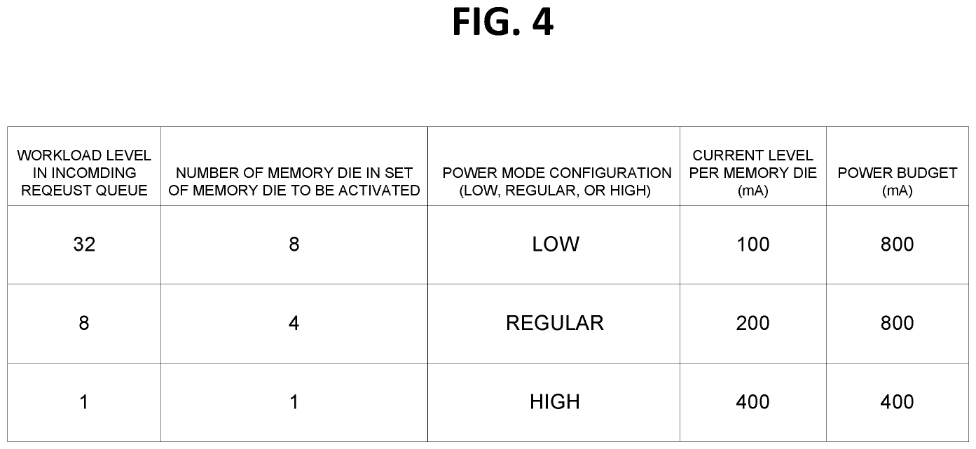

FIG. 4 illustrates a table including examples of power mode configurations established by the processing device in view of an identified workload level in the incoming request queue, a set of memory dies to be activated, and a power budget. In the examples shown in FIG. 4, the processing logic can place a memory die in one of three power mode configurations: a low power mode configuration having a per memory die current level of 100 mA, a medium power mode configuration having a per memory die current level of 200 mA, and a high power mode configuration having a per memory die current level of 400 mA.

In one example shown in FIG. 4, the processing logic determines a workload level in the incoming request queue of thirty-two operations. In view of the workload level in the incoming request queue, the processing logic determines a set of eight memory dies to activate to perform the workload level. In view of the power budget of 800 mA, the processing logic determines that the eight memory dies are to be placed in the low power mode configuration. In this example, placement of the eight memory dies in the low power mode configuration enables the workload level in the incoming request queue to be performed within the identified power budget.

In another example shown in FIG. 4, the processing logic determines a workload level in the incoming request queue of eight operations. In view of the workload level in the incoming request queue, the processing logic determines a set of four memory dies to activate to perform the workload level. In view of the power budget of 800 mA, the processing logic determines that the four memory dies are to be placed in the regular power mode configuration. In this example, placement of the four memory dies in the regular power mode configuration enables the workload level in the incoming request queue to be performed within the identified power budget, while optimizing the power mode configuration for the set of memory dies (e.g., placing the set of memory dies in a power mode configuration having a highest applicable setting (e.g., regular) in view of the workload level and power budget).

In a further example shown in FIG. 4, the processing logic determines a workload level in the incoming request queue of one operation. In view of the workload level in the incoming request queue, the processing logic determines a set of one memory die to activate to perform the workload level. In view of the power budget of 800 mA, the processing logic determines that the one memory die is to be placed in the high power mode configuration. In this example, placement of the activated memory die in the high power mode configuration enables the workload level in the incoming request queue to be performed within the identified power budget, while optimizing the power mode configuration for the set of memory dies (e.g., placing the one memory die in a power mode configuration having a highest applicable setting in view of the workload level and power budget).

In an embodiment, the power mode configuration can be one of a low power mode configuration, a medium power mode configuration, and a high power mode configuration. In an embodiment, each of the applicable power mode configurations (e.g., low, medium, and high) are associated with a corresponding set of memory die parameters values (or value ranges). In an embodiment, the low power mode configuration is associated with a first set of parameter values, the medium power mode configuration is associated with a second set of parameter values, and the high power mode configuration is associated with a third set of parameter values. In an embodiment, the different power mode configurations and corresponding set of parameter values can be predefined, such that the processing logic can identify the set of values corresponding to the desired power mode configuration. The multiple different power mode configurations represent a relative level of power consumed by each of the memory die when activated in the execution of a corresponding operation.

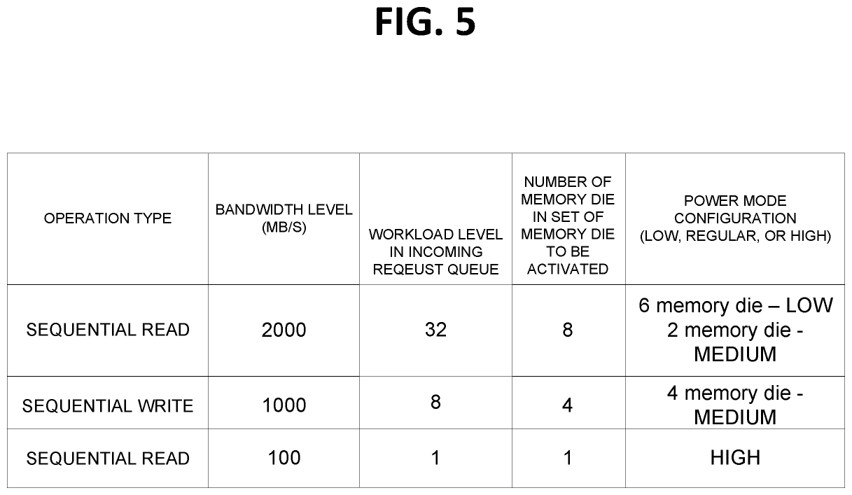

FIG. 5 illustrates a table including examples of power mode configurations established by the processing device in view of an identified workload level in the incoming request queue represented by a requested operation type and corresponding bandwidth level requirement, according to embodiments of the present disclosure. In an example shown in FIG. 5, a host system can issue a request for a sequential read operation requiring a bandwidth level of 2000 MB/s with a 800 mA power budget. The power mode component 113 can determine a workload level in the incoming request queue of thirty-two read commands and calculate that eight memory dies are to be activated to service the 2000 MB/s bandwidth level, where each memory die has a read throughput of 250 MB/s. In an embodiment, the set of eight memory dies are identified for activation to perform the read operations in parallel. To meet the 800 mA power budget, the power mode component 113 can configure six of the eight active memory dies to a low power mode configuration and the remaining two active memory dies to a medium power mode configuration.

In another example shown in FIG. 5, a host system can issue a request for a sequential write operation requiring a bandwidth level of 1000 MB/s with a 800 mA power budget. The power mode component 113 can determine a workload level in the incoming request queue of eight 128 kB sized write commands and identify a set of four memory dies to activate to perform the sequential write operation, because, in this example, each memory die can process 32 kB each. To meet 800 mA power budget and optimize power performance, the power mode component 113 can configure all four active memory dies to a medium power mode configuration.

In yet another example shown in FIG. 5, a host system can issue a request for a sequential read operation requiring a bandwidth level of 100 MB/s with a 400 mA power budget. In this example, the power mode component 113 can determine a workload level in the incoming request queue of one large write operation and identify a set of one memory die to activate to perform the sequential write operation, because the large write operation has low throughput requirements and can be serviced by one memory die having a 250 MB/s throughput. To meet 400 mA power budget and optimize power performance, the power mode component 113 can configure the one active memory die to a high power mode configuration.

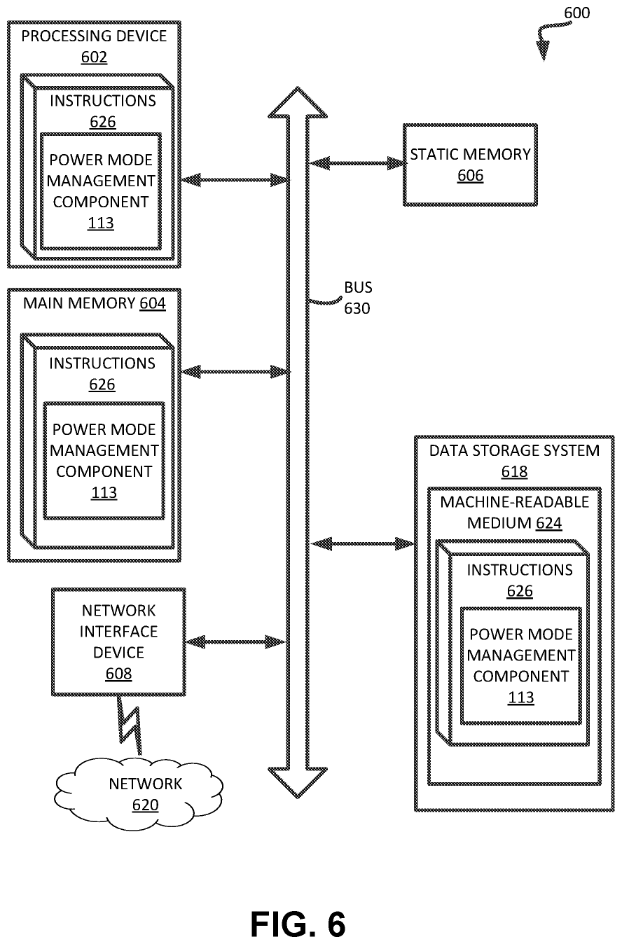

FIG. 6 illustrates an example machine of a computer system 600 within which a set of instructions, for causing the machine to perform any one or more of the methodologies discussed herein, can be executed. In some embodiments, the computer system 600 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to a power mode management component 113 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, digital or non-digital circuitry, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a data storage system 618, which communicate with each other via a bus 630.

Processing device 602 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 602 can also be one or more special-purpose processing devices such as an application specific integrated circuit (ASIC), a field programmable gate array (FPGA), a digital signal processor (DSP), network processor, or the like. The processing device 602 is configured to execute instructions 626 for performing the operations and steps discussed herein. The computer system 600 can further include a network interface device 608 to communicate over the network 620.

The data storage system 618 can include a machine-readable storage medium 624 (also known as a computer-readable medium) on which is stored one or more sets of instructions 626 or software embodying any one or more of the methodologies or functions described herein. The instructions 626 can also reside, completely or at least partially, within the main memory 604 and/or within the processing device 602 during execution thereof by the computer system 600, the main memory 604 and the processing device 602 also constituting machine-readable storage media. The machine-readable storage medium 624, data storage system 618, and/or main memory 604 can correspond to the memory sub-system 110 of FIG. 1.

In one embodiment, the instructions 626 include instructions to implement functionality corresponding to a data protection component (e.g., the power mode management component 113 of FIG. 1). While the machine-readable storage medium 624 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A method comprising:
determining, by a processing device of a memory sub-system, a workload level in an incoming request queue based on one or more operations requested by a host system for execution by the memory sub-system;
identifying, based on the workload level in the incoming request queue, a set of memory dies of the memory sub-system to be activated for execution of the one or more operations;
determining, based on a power budget level, a power mode configuration for a memory die of the set of memory dies; and
configuring one or more parameters of the memory die to establish the power mode configuration.

2. The method of claim 1, wherein the power mode configuration is selected from a set of power mode configurations comprising a low power mode configuration, a medium power mode configuration, or high power mode configuration.

3. The method of claim 2, wherein a first power level corresponding to the low power mode configuration is lower than a second power level corresponding to the medium power configuration; and wherein a third power level corresponding to the high power mode configuration is higher than the second power level corresponding to the medium power configuration.

4. The method of claim 1, wherein the one or more parameters of the memory die are tuned to a set of parameter values corresponding to a high power mode configuration to establish the high power mode configuration.

5. The method of claim 1, wherein the set of parameter values includes one of: an internal trim value, a latch value, a register value, a flag value, a charge pump voltage level, a charge pump clock frequency, an internal bias current, or a charge pump output resistance.

6. The method of claim 1, further comprising determining one of a low power mode configuration, a medium power mode configuration, or a high power mode configuration for each memory die of the set of memory dies.

7. The method of claim 1, wherein the workload level in the incoming request queue is determined based at least in part on a type of the one or more operations and a bandwidth level corresponding with the execution of the one or more operations.

8. A non-transitory computer readable medium comprising instructions, which when executed by a processing device, cause the processing device to perform operations comprising:
determining a workload level in an incoming request queue based on one or more operations requested by a host system for execution by a memory sub-system;
identifying, based on the workload level in the incoming request queue, a set of memory dies of the memory sub-system to be activated for execution of the one or more operations;
configuring one or more parameters of at least a first portion of the set of memory dies to a first set of parameter values corresponding to a low power mode configuration; and
configuring one or more parameters of at least a second portion of the set of memory dies to a second set of parameter values corresponding to a high power mode configuration.

9. The non-transitory computer readable medium of claim 8, wherein configuring the one or more parameters to the second set of parameter values comprises at least one of setting a charge pump to a higher output voltage, speeding up a charge pump clock frequency, increasing an internal bias current, decreasing a charge pump output resistance, or changing from serialized single plane operations to multiple plane parallel operations.

10. The non-transitory computer readable medium of claim 8, wherein a power level associated with the high power mode configuration is higher than a threshold power level.

11. The non-transitory computer readable medium of claim 8, the operations further comprising establishing at least an additional portion of the set of memory dies to a medium power mode configuration.

12. The non-transitory computer readable medium of claim 8, the operations further comprising:
identifying a power budget level; and
determining placement of at least the portion of the set of memory dies in the high power mode configuration based at least in part on the power budget level.

13. The non-transitory computer readable medium of claim 8, wherein operation of at least the set of memory dies in the high power mode configuration produces a power level within the power budget level.

14. A system comprising:
a memory device; and
a processing device, operatively coupled with the memory device, to perform operations comprising:
determining, by a processing device, a workload level in an incoming request queue based on one or more operations requested by a host system for execution by a memory sub-system;
identifying, based on the workload level in the incoming request queue, a set of memory dies of the memory sub-system to be activated for execution of the one or more operations;
determining, based on a power budget level, a power mode configuration for a memory die of the set of memory dies; and
configuring one or more parameters of the memory die to establish the power mode configuration.

15. The system of claim 14, wherein the power mode configuration is selected from a set of power mode configurations comprising a low power mode configuration, a medium power mode configuration, or high power mode configuration.

16. The system of claim 15, wherein a first power level corresponding to the low power mode configuration is lower than a second power level corresponding to the medium power configuration; and wherein a third power level corresponding to the high power mode configuration is higher than the second power level corresponding to the medium power configuration.

17. The system of claim 14, wherein the one or more parameters of the memory die are configured to a set of parameter values corresponding to a high power mode configuration to establish the high power mode configuration.

18. The system of claim 14, wherein the set of parameter values correspond to one or more an internal trim value, a latch value, a register value, a flag value, a charge pump voltage level, a charge pump clock frequency, an internal bias current, or a charge pump output resistance.

19. The system of claim 14, the operations further comprising determining one of a low power mode configuration, a medium power mode configuration, or a high power mode configuration for each memory die of the set of memory dies.

20. The system of claim 14, wherein the workload level in the incoming request queue is determined based at least in part on a type of the one or more operations and a bandwidth level corresponding with the execution of the one or more operations.
